(19) United States
(12) Patent Application Publication
(10) Pub. No.: US 2021/0058076 A1
(43) Pub. Date: Feb. 25, 2021

(54) HYBRID FIN FLIP FLOP CIRCUIT ARCHITECTURE

(71) Applicant: QUALCOMM Incorporated, San Diego, CA (US)

(72) Inventors: Andi ZHAO, San Diego, CA (US); Ramaprasath VILANGUDIPITCHAI, San Diego, CA (US); Hyeokjin LIM, San Diego, CA (US); Seung Hyuk KANG, San Diego, CA (US)

(21) Appl. No.: 16/548,517

(22) Filed: Aug. 22, 2019

(51) Int. Cl. H03K 3/356; H03K 3/012; H03K 3/037

(52) U.S. Cl. CPC H03K 3/356017; H03K 3/037; H03K 3/012

(57) ABSTRACT

A hybrid fin flip flop circuit may comprise a mixture of 1-fin transistors and multi-fin transistors. In one example, a flip flop circuit may comprise 1-fin transistors in at least one of the critical paths of the flip flop circuit such as the drive circuit, the input circuit, or the output circuit. In one example, a flip flop circuit may include: an input circuit; a clock driver circuit; an output circuit; and a latch circuit; wherein one of the input circuit, the clock driver circuit, or the output circuit comprises a multi-fin transistor and the latch circuit comprises a plurality of 1-fin transistors.

### FIELD OF DISCLOSURE

This disclosure relates generally to flip flop circuits, and more specifically, but not exclusively, to hybrid fin flip flop circuit architecture.

### BACKGROUND

A current trend in circuit design is reducing power consumption and area while maintaining a high performance standard. In other words, balancing the power, performance, and area (PPA) factors to achieve a desired result. Reducing the power consumption of flip flops is critical for conventional system on chip designs due to the high usage of flip flops in modern circuits. For example, circuit designs for mobile devices with higher power and area constraints use flip flops and flop trays more than any other standard design cell. In addition, most of the digital logic areas are occupied by flip flops/sequential circuits.

In modern designs, multi-fin devices are used almost exclusively. While single or 1-fin devices (with reduced capacitance, slower, and lower drive current compared to multi-fin devices) can reduce power consumption, their usage for standard cell libraries, in general, have not been allowed due to inherently large device variation experience in 1-fin devices. Currently, no known semiconductor fabrication shop offers a 1-fin device for logic design cells.

Accordingly, there is a need for systems, apparatus, and methods that overcome the deficiencies of conventional approaches including the methods, system and apparatus provided hereby, such as hybrid fin flip flop circuit architectures.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In one aspect, a flip flop circuit comprises: an input circuit; a clock driver circuit; an output circuit; and a latch circuit; wherein one of the input circuit, the clock driver circuit, or the output circuit comprises a multi-fin transistor and the latch circuit comprises a plurality of 1-fin transistors.

In another aspect, a flip flop circuit comprises: means for receiving an input; means for driving a clock; means for outputting an output; and means for latching the input; wherein one of the means for receiving the input, the means for driving the clock, or the means for outputting the output comprises a multi-fin transistor, and the means for latching the input comprises a plurality of 1-fin transistors.

In still another aspect, a mobile device comprises: a processor; an antenna coupled to the processor; a memory coupled to the processor; and a flip flop circuit comprising: an input circuit; a clock driver circuit; an output circuit; and a latch circuit; wherein one of the input circuit, the clock driver circuit, or the output circuit comprises a multi-fin transistor, and the latch circuit comprises a plurality of 1-fin transistors.

In still another aspect, a method for operating a flip flop circuit comprises: inputting an input signal with an input circuit; driving a clock signal with a clock driver circuit; outputting an output with an output circuit; and latching the input with a latch circuit; wherein one of the input circuit, the clock driver circuit, or the output circuit comprises a multi-fin transistor, and the latch circuit comprises a plurality of 1-fin transistors.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 illustrates an exemplary flip flop with 2-fin clock drivers in accordance with some examples of the disclosure;

FIG. 2 illustrates an exemplary flip flop with 2-fin clock drivers and output inverter in accordance with some examples of the disclosure;

FIG. 3 illustrates an exemplary flip flop with 2-fin clock drivers, output inverter, and input stacks in accordance with some examples of the disclosure;

FIG. 4 illustrates an exemplary flip flop layout without metal layers in accordance with some examples of the disclosure;

FIG. 5 illustrates an exemplary flip flop layout in accordance with some examples of the disclosure;

FIG. 6 illustrates an exemplary partial method of operating a flip flop in accordance with some examples of the disclosure;

FIG. 7 illustrates an exemplary mobile device in accordance with some examples of the disclosure; and

FIG. 8 illustrates various electronic devices that may be integrated with any of the aforementioned devices or methods in accordance with some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

The exemplary methods, apparatus, and systems disclosed herein mitigate shortcomings of the conventional methods, apparatus, and systems, as well as other previously unidentified needs. For example, a hybrid-fin flip-flop circuit architecture that co-integrates both 1-fin and 2-fin transistors for power saving while minimizing tradeoffs in variation and performance. By adopting 1-fin devices in place of select multi-fin devices, power savings may be accomplished without sacrificing performance. In some examples, the impact of 1-fin's high variations may be reduced but may result in performance trade-offs. These trade-offs may be minimized with optimization of the flip flop area and timing needs that provides a clean circuit sign-off, especially at low voltage corners. This may result in a hybrid-fin flip-flop design architecture that achieves lower power consumption while containing the variability and sustaining the performance.

To achieve these benefits, a flip flop design must identify and convert non-critical devices from multi-fins to 1-fin for power saving using an optimal circuit topology architecture that considers timing, area, and devices sensitivity, avoid incurring an area penalty by using the same size for all the devices in one “island” (either 1-fin or multi-fins), and maintain acceptable timing by keeping one or more critical paths (e.g., clk2q or output inverter, hold or clock drivers, and setup or input stacks) as multi-fin devices. This may result in better PPA trade-offs as opposed to an all multi-fin device, an all 1-fin device, or a random mix of 1-fin and multi-fin devices.

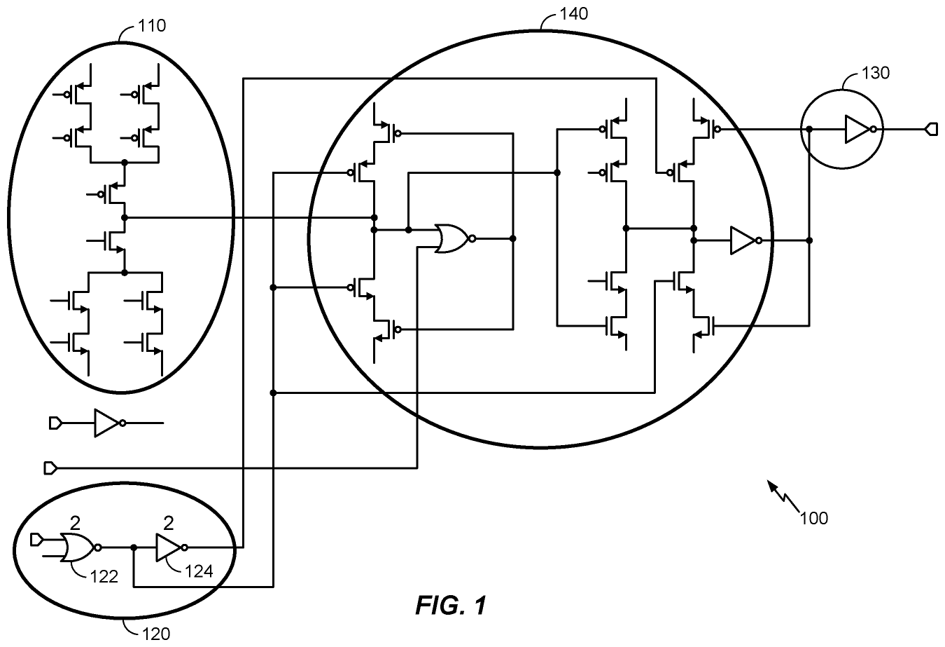

FIG. 1 illustrates an exemplary flip flop with 2-fin clock drivers in accordance with some examples of the disclosure. As shown in FIG. 1, a flip flop circuit 100 may include an input circuit 110 configured to receive an input, a clock driver circuit 120 configured to drive a clock signal for the flip flop circuit 100, an output circuit 130 configured to output an output of the flip flop circuit 100, and a latch circuit 140 configured to latch the input. The transistors and transistor based devices (e.g., inverters, logic gates etc.) illustrated in FIG. 1 are 1-fin transistor devices except for the transistors in the clock driver circuit 120. The clock driver circuit 120 may include a first logic gate 122 and a first inverter 124. The transistors in the first logic gate 122 and the first inverter 124 may be multi-fin transistors, such as the 2-fin transistors illustrated. While a 2-fin transistor is illustrated throughout this description, it should be understood that any multi-fin transistor may be used. The flip flop circuit 100 (or latch) is a circuit that has two stable states and can be used to store state information. The flip flop circuit 100 may be made to change states by signals applied to one or more control inputs and may have one or more outputs. The flip flop circuit 100 may be used as the basic storage element in sequential logic and may be a fundamental building block of digital electronics systems used in computers, communications, mobile devices and many other types of systems.

The flip flop circuit 100 may be used as a data storage element that stores a single bit (binary digit) of data; one of its two states represents a “one” and the other represents a “zero”. Such data storage can be used for storage of states, and such a circuit is described as sequential logic in electronics. When used in a finite-state machine, the output and next state depend not only on its current input, but also on its current state (and hence, previous inputs). The flip flop circuit 100 may also be used for counting of pulses, and for synchronizing variably-timed input signals to some reference timing signal. The flip flop circuit 100 is edge-triggered (synchronous, or clocked), but may also be configured as level-triggered (asynchronous, transparent or opaque). By replacing the multi-fin transistors in the flip flop circuit 100 with 1-fin transistors with the exception of the clock driver circuit 120, the flip flop circuit 100 reduces its power consumption while maintaining good hold and set up timing within the circuit.

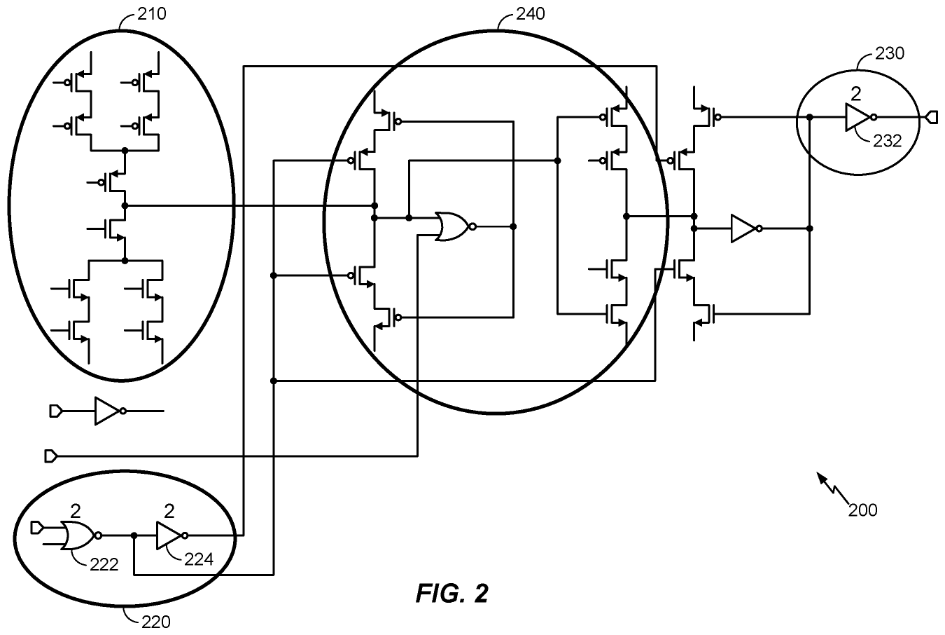

FIG. 2 illustrates an exemplary flip flop with 2-fin clock drivers and output inverter in accordance with some examples of the disclosure. As shown in FIG. 2, a flip flop circuit 200 (e.g., flip flop circuit 100) may include an input circuit 210 configured to receive an input, a clock driver circuit 220 configured to drive a clock signal for the flip flop circuit 200, an output circuit 230 configured to output an output of the flip flop circuit 200, and a latch circuit 240 configured to latch the input. The transistors and transistor based devices (e.g., inverters, logic gates etc.) illustrated in FIG. 2 are 1-fin transistor devices except for the transistors in the clock driver circuit 220 and the output circuit 230. The clock driver circuit 220 may include a first logic gate 222 and a first inverter 224. The transistors in the first logic gate 222 and the first inverter 224 may be multi-fin transistors, such as the 2-fin transistors illustrated. The output circuit 230 may include a second inverter 232 that includes a multi-fin transistor, such as the 2-fin transistor illustrated. By replacing the multi-fin transistors in the flip flop circuit 200 with 1-fin transistors with the exception of the clock driver circuit 220 and the output circuit 230, the flip flop circuit 200 reduces its power consumption while maintaining good output (clk2q), hold, and set up timing within the circuit.

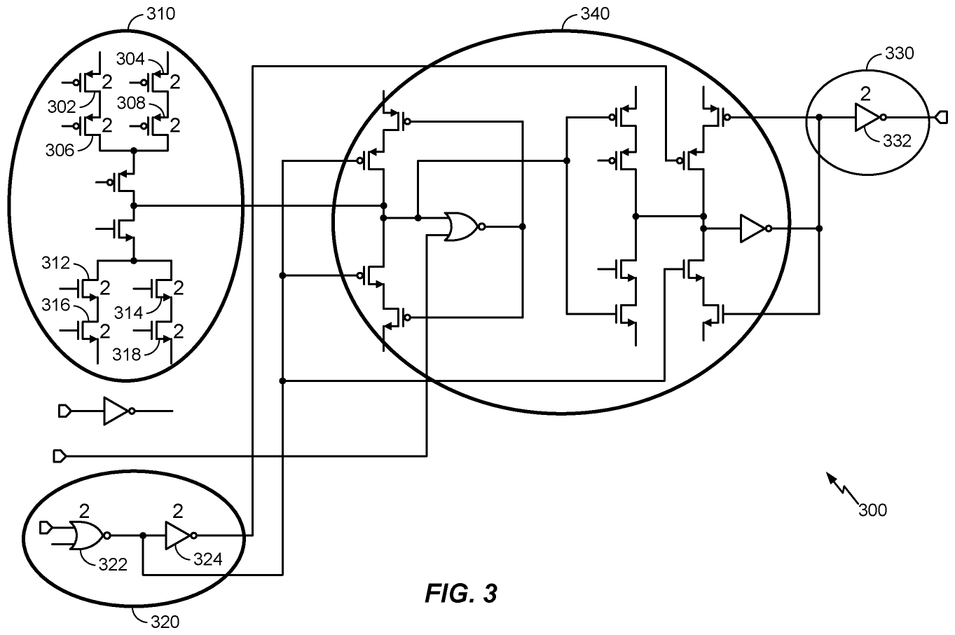

FIG. 3 illustrates an exemplary flip flop with 2-fin clock drivers, output inverter, and input stacks in accordance with some examples of the disclosure. As shown in FIG. 3, a flip flop circuit 300 (e.g., flip flop circuit 100 and flip flop circuit 200) may include an input circuit 310 configured to receive an input, a clock driver circuit 320 configured to drive a clock signal for the flip flop circuit 300, an output circuit 330 configured to output an output of the flip flop circuit 300, and a latch circuit 340 configured to latch the input. The transistors and transistor based devices (e.g., inverters, logic gates etc.) illustrated in FIG. 3 are 1-fin transistor devices except for the transistors in the input circuit 310, the clock driver circuit 320, and the output circuit 330. The clock driver circuit 320 may include a first logic gate 322 and a first inverter 324. The transistors in the first logic gate 322 and the first inverter 324 may be multi-fin transistors, such as the 2-fin transistors illustrated. The output circuit 330 may include a second inverter 332 that includes a multi-fin transistor, such as the 2-fin transistor illustrated. The input circuit 310 may include one or more multi-fin transistors, such as the paired 2-fin transistors of the input stacks shown including a first transistor 302, a second transistor 304, a third transistor 306, a fourth transistor 308, a fifth transistor 312, a sixth transistor 314, a seventh transistor 316, and an eighth transistor 318. By replacing the multi-fin transistors in the flip flop circuit 300 with 1-fin transistors with the exception of the input circuit 310, the clock driver circuit 320, and the output circuit 330, the flip flop circuit 300 reduces its power consumption while maintaining good output (clk2q), hold, and set up timing within the circuit.

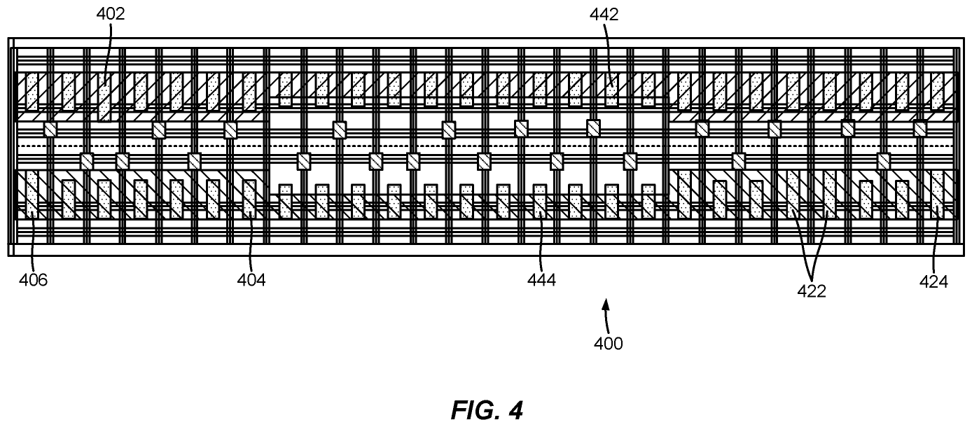

FIG. 4 illustrates an exemplary flip flop layout without metal layers in accordance with some examples of the disclosure. As shown in FIG. 4, a flip flop circuit 400 (e.g., flip flop circuit 100, flip flop circuit 200, and flip flop circuit 300) may include a plurality of 1-fin transistors, such as a ninth transistor 442 and tenth transistor 444 for example, and a plurality of multi-fin transistors, such as a first logic gate 422, a first inverter 424, a first transistor 402, a second transistor 404, and a third transistor 406 for example.

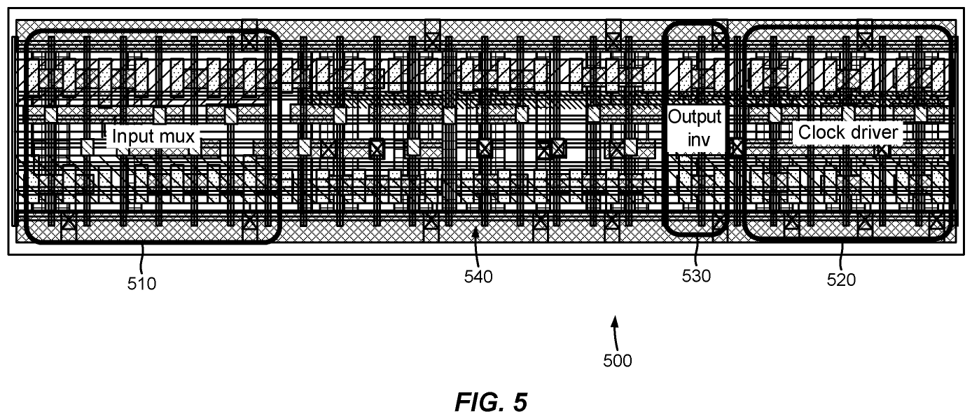

FIG. 5 illustrates an exemplary flip flop layout in accordance with some examples of the disclosure. As shown in FIG. 5, a flip flop circuit 500 (e.g., flip flop circuit 100, flip flop circuit 200, flip flop circuit 300, and flip flop circuit 400) may include an input circuit 510 configured to receive an input, a clock driver circuit 520 configured to drive a clock signal for the flip flop circuit 500, an output circuit 530 configured to output an output of the flip flop circuit 500, and a latch circuit 540 configured to latch the input. As shown and discussed above, the flip flop circuit 500 may include multi-fin transistors in one or more of the critical power and timing paths, such as the input circuit 510, the clock driver circuit 520, or the output circuit 530.

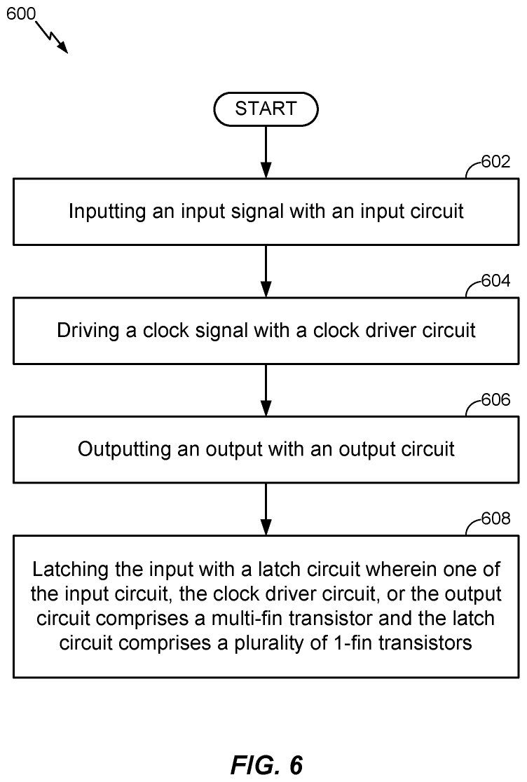

FIG. 6 illustrates an exemplary partial method for operating a flip flop in accordance with some examples of the disclosure. As shown in FIG. 6, a partial method 600 may begin in block 602 with inputting an input signal with an input circuit. The partial method 600 may continue in block 604 with driving a clock signal with a clock driver circuit. The partial method 600 may continue in block 606 with outputting an output with an output circuit. The partial method 600 may conclude in block 608 with latching the input with a latch circuit; wherein one of the input circuit, the clock driver circuit, or the output circuit comprises a multi-fin transistor and the latch circuit comprises a plurality of 1-fin transistors.

Alternatively, the partial method 600 may include the clock driver circuit comprising a multi-fin transistor; the output circuit comprising a multi-fin transistor; and/or the input circuit comprising a multi-fin transistor. Alternatively, the partial method 600 may include the input circuit comprising a plurality of multi-fin transistors or a plurality of paired multi-fin transistors.

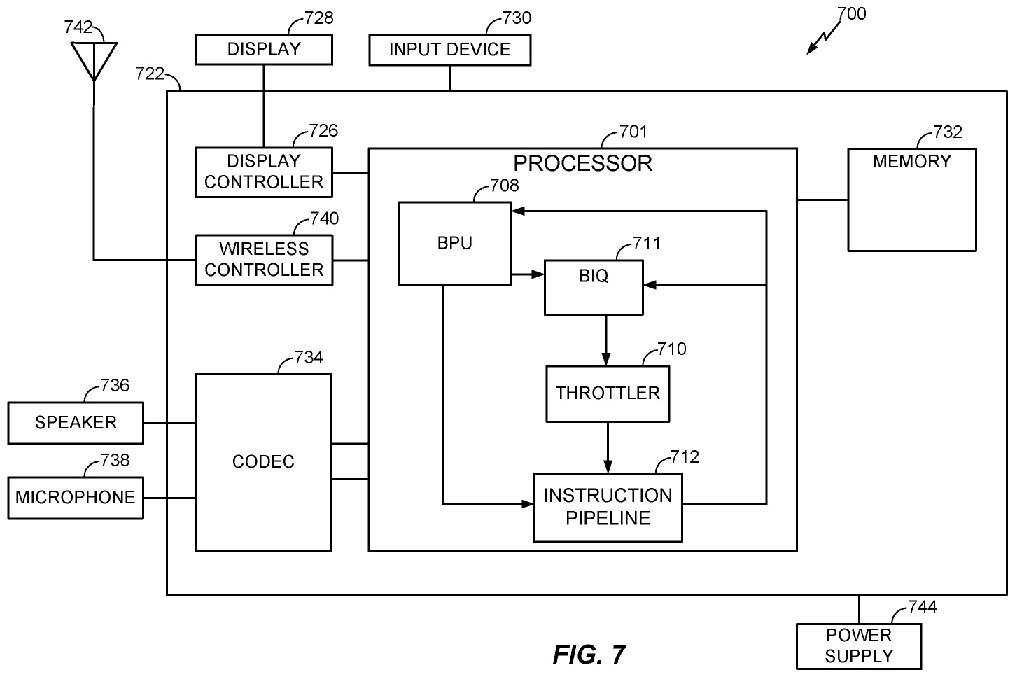

FIG. 7 illustrates an exemplary mobile device in accordance with some examples of the disclosure. Referring now to FIG. 7, a block diagram of a mobile device that is configured according to exemplary aspects is depicted and generally designated 700. In some aspects, mobile device 700 may be configured as a wireless communication device. As shown, mobile device 700 includes processor 701, which may be configured to implement the methods described herein in some aspects. Processor 701 is shown to comprise instruction pipeline 712, buffer processing unit (BPU) 708, branch instruction queue (BIQ) 711, and throttler 710 as is well known in the art. Other well-known details (e.g., counters, entries, confidence fields, weighted sum, comparator, etc.) of these blocks have been omitted from this view of processor 701 for the sake of clarity.

Processor 701 may be communicatively coupled to memory 732 over a link, which may be a die-to-die or chip-to-chip link. Mobile device 700 also include display 728 and display controller 726, with display controller 726 coupled to processor 701 and to display 728.

In some aspects, FIG. 7 may include coder/decoder (CODEC) 734 (e.g., an audio and/or voice CODEC) coupled to processor 701; speaker 736 and microphone 738 coupled to CODEC 734; and wireless controller 740 (which may include a modem) coupled to wireless antenna 742 and to processor 701.

In a particular aspect, where one or more of the above-mentioned blocks are present, processor 701, display controller 726, memory 732, CODEC 734, and wireless controller 740 can be included in a system-in-package or system-on-chip device 722. Input device 730 (e.g., physical or virtual keyboard), power supply 744 (e.g., battery), display 728, input device 730, speaker 736, microphone 738, wireless antenna 742, and power supply 744 may be external to system-on-chip device 722 and may be coupled to a component of system-on-chip device 722, such as an interface or a controller.

It should be noted that although FIG. 7 depicts a mobile device, processor 701 and memory 732 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

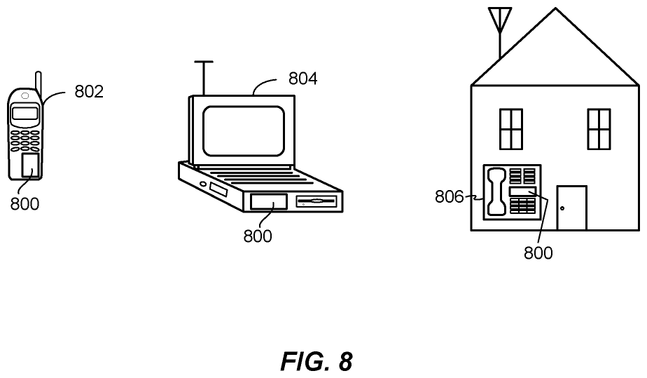

FIG. 8 illustrates various electronic devices that may be integrated with any of the aforementioned devices or methods in accordance with some examples of the disclosure. For example, a mobile phone device 802, a laptop computer device 804, and a fixed location terminal device 806 may include an integrated device 800 as described herein. The integrated device 800 may be, for example, any of the integrated circuits, dies, integrated devices, integrated device packages, integrated circuit devices, device packages, integrated circuit (IC) packages, package-on-package devices described herein. The devices 802, 804, 806 illustrated in FIG. 8 are merely exemplary. Other electronic devices may also feature the integrated device 800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

It will be appreciated that various aspects disclosed herein can be described as functional equivalents to the structures, materials and/or devices described and/or recognized by those skilled in the art. For example, in one aspect, a flip flop circuit may include means for receiving an input (e.g., input circuit 110, input circuit 210; input circuit 310, and input circuit 510); means for driving a clock (e.g., clock driver circuit 120, clock driver circuit 220, clock driver circuit 320, and clock driver circuit 520); means for outputting an output (e.g., output circuit 130, output circuit 230, output circuit 330, and output circuit 530); and means for latching the input (e.g., latch circuit 140, latch circuit 240, latch circuit 340, and latch circuit 540); wherein one of the means for receiving the input, the means for driving the clock, or the means for outputting the output comprises a multi-fin transistor and the means for latching the input comprises a plurality of 1-fin transistors. It will be appreciated that the aforementioned aspects are merely provided as examples and the various aspects claimed are not limited to the specific references and/or illustrations cited as examples.

One or more of the components, processes, features, and/or functions illustrated in FIGS. 1-8 may be rearranged and/or combined into a single component, process, feature or function or incorporated in several components, processes, or functions. Additional elements, components, processes, and/or functions may also be added without departing from the disclosure. It should also be noted that FIGS. 1-8 and its corresponding description in the present disclosure is not limited to dies and/or ICs. In some implementations, FIGS. 1-8 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.).

These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5 (both expressly incorporated herein in their entirety).

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples and is not intended to be limiting of examples of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, actions, operations, elements, and/or components, but do not preclude the presence or addition of one or more other features, integers, actions, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

Further, those of skill in the art will appreciate that the various illustrative logical blocks, modules, circuits, and algorithm actions described in connection with the examples disclosed herein may be implemented as electronic hardware, computer software, or combinations of both. To clearly illustrate this interchangeability of hardware and software, various illustrative components, blocks, modules, circuits, and actions have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or a plurality of claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions of this method.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

1. A flip flop circuit comprising:
an input circuit;
a clock driver circuit;
an output circuit; and
a latch circuit;
wherein one of the input circuit, the clock driver circuit, or the output circuit comprises a multi-fin transistor and the latch circuit comprises a plurality of 1-fin transistors.

2. The flip flop circuit of claim 1, wherein the clock driver circuit comprises a multi-fin transistor.

3. The flip flop circuit of claim 2, wherein the clock driver circuit comprises a plurality of multi-fin transistors.

4. The flip flop circuit of claim 2, wherein the output circuit comprises a multi-fin transistor.

5. The flip flop circuit of claim 4, wherein the output circuit comprises an inverter with the multi-fin transistor.

6. The flip flop circuit of claim 4, wherein the input circuit comprises a multi-fin transistor.

7. The flip flop circuit of claim 6, wherein the input circuit comprises a plurality of multi-fin transistors.

8. The flip flop circuit of claim 1, wherein the flip flop circuit is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

9. A flip flop circuit comprising:
means for receiving an input;
means for driving a clock;
means for outputting an output; and
means for latching the input;
wherein one of the means for receiving the input, the means for driving the clock, or the means for outputting the output comprises a multi-fin transistor and the means for latching the input comprises a plurality of 1-fin transistors.

10. The flip flop circuit of claim 9, wherein the means for driving the clock comprises a multi-fin transistor.

11. The flip flop circuit of claim 10, wherein the means for driving the clock comprises a plurality of multi-fin transistors.

12. The flip flop circuit of claim 10, wherein the means for outputting the output comprises a multi-fin transistor.

13. The flip flop circuit of claim 12, wherein the means for outputting the output comprises an inverter with the multi-fin transistor.

14. The flip flop circuit of claim 12, wherein the means for receiving the input comprises a multi-fin transistor.

15. The flip flop circuit of claim 14, wherein the means for receiving the input comprises a plurality of multi-fin transistors.

16. The flip flop circuit of claim 9, wherein the flip flop circuit is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

17. A mobile device comprising:
a processor;
an antenna coupled to the processor;
a memory coupled to the processor; and
a flip flop circuit comprising:
an input circuit;
a clock driver circuit;
an output circuit; and
a latch circuit;
wherein one of the input circuit, the clock driver circuit, or the output circuit comprises a multi-fin transistor and the latch circuit comprises a plurality of 1-fin transistors.

18. The mobile device of claim 17, wherein the clock driver circuit comprises a multi-fin transistor.

19. The mobile device of claim 18, wherein the clock driver circuit comprises a plurality of multi-fin transistors.

20. The mobile device of claim 18, wherein the output circuit comprises a multi-fin transistor.

21. The mobile device of claim 20, wherein the output circuit comprises an inverter with the multi-fin transistor.

22. The mobile device of claim 20, wherein the input circuit comprises a multi-fin transistor.

23. The mobile device of claim 22, wherein the input circuit comprises a plurality of multi-fin transistors.

24. The mobile device of claim 18, wherein the mobile device is incorporated into a device selected from the group consisting of a music player, a video player, an entertainment unit, a navigation device, a communications device, a mobile phone, a smartphone, a personal digital assistant, a fixed location terminal, a tablet computer, a computer, a wearable device, a laptop computer, a server, and a device in an automotive vehicle.

25. A method for operating a flip flop circuit, the method comprising:
inputting an input signal with an input circuit;
driving a clock signal with a clock driver circuit;
outputting an output with an output circuit; and
latching the input signal with a latch circuit;
wherein one of the input circuit, the clock driver circuit, or the output circuit comprises a multi-fin transistor and the latch circuit comprises a plurality of 1-fin transistors.

26. The method of claim 25, wherein the clock driver circuit comprises a multi-fin transistor.

27. The method of claim 26, wherein the output circuit comprises a multi-fin transistor.

28. The method of claim 27, wherein the input circuit comprises a multi-fin transistor.

29. The method of claim 28, wherein the input circuit comprises a plurality of multi-fin transistors.

30. The method of claim 28, wherein the input circuit comprises a plurality of paired multi-fin transistors.
